(19) United States
(12) Patent Application Publication
(10) Pub. No.: US 2025/0224681 A1
(43) Pub. Date: Jul. 10, 2025

(54) COOLING DEVICE FOR COOLING A POSITION-SENSITIVE COMPONENT OF A LITHOGRAPHY SYSTEM

(71) Applicants: Carl Zeiss SMT GmbH, Oberkochen (DE); ASML Netherlands B.V., Veldhoven (NL)

(72) Inventors: Matthias FETZER, Stuttgart (DE); Luca METTENLEITER, Neresheim (DE); Richard STEIJNS, Veldhoven (NL)

(21) Appl. No.: 19/092,004

(22) Filed: Mar. 27, 2025

Related U.S. Application Data
(63) Continuation of application No. PCT/EP2023/072998, filed on Aug. 22, 2023.

(30) Foreign Application Priority Data
Sep. 30, 2022 (DE) 10 2022 125 354.6

(51) Int. Cl. G03F 7/20; G03F 7/00

(52) U.S. Cl. CPC G03F 7/2041; G03F 7/70233

(57) ABSTRACT

A cooling device (200) for cooling a position-sensitive component (102) of a lithography system (1), comprising a cooling line (206) with a liquid chamber (218) for conducting a cooling liquid (112) to the position-sensitive component (102) and a gas chamber (220) for receiving a gas (222), and an elastic separating membrane (224) which is arranged inside the cooling line (206) and separates the gas chamber (220) from the liquid chamber (218).

### CROSS REFERENCE TO RELATED APPLICATIONS

This is a Continuation of International Application PCT/EP2023/072998, which has an international filing date of Aug. 22, 2023, and which claims the priority of German Patent Application 10 2022 125 354.6, filed Sep. 30, 2022. The disclosures of both applications are incorporated in their respective entireties into the present Continuation by reference.

### FIELD OF THE INVENTION

The present invention relates to a cooling device for cooling a position-sensitive component of a lithography apparatus, a corresponding lithography apparatus and a method for operating a cooling device of a lithography apparatus.

### BACKGROUND

Microlithography is used for producing microstructured components, for example integrated circuits. The microlithography process is performed using a lithography apparatus, which comprises an illumination system and a projection system. The image of a mask (reticle) illuminated by the illumination system is projected by the projection system onto a substrate, for example a silicon wafer, which is coated with a light-sensitive layer (photoresist) and arranged in the image plane of the projection system, in order to transfer the mask structure to the light-sensitive coating of the substrate.

Driven by the desire for ever smaller structures in the production of integrated circuits, lithography apparatuses that use extreme ultraviolet (EUV) light at a wavelength in the range from 0.1 nm to 30 nm, in particular 13.5 nm, are currently under development. Since most materials absorb light at this wavelength, reflective optical units, i.e. mirrors, must be used in such EUV lithography apparatuses instead of refractive optical units, i.e. lens elements, as has been done up to this point.

The demands on the accuracy and precision of the imaging properties of lithography apparatuses are constantly increasing. From a dynamic point of view, the influence of disturbance inputs on the movement of various position-sensitive component parts of the lithography apparatus must be minimized in this context. For example, very precise positioning of optical components, especially mirrors, of the lithography apparatus is required. Dynamic disturbance excitations of optical components may be created, for example, by the movement of other component parts of the lithography apparatus or by acoustic disturbances. Acoustic disturbances are transmitted to position-sensitive component parts of the lithography apparatus, for example as pressure fluctuations of cooling liquids in cooling lines of a cooling device of the lithography apparatus.

As the complexity of lithography apparatuses increases further, the expectation is that there will be more dynamic disturbance excitations within and outside of the system, and so additional mechanisms for the suppression or compensation of said disturbance excitations are desirable and necessary.

### SUMMARY

Against this background, a problem addressed by the present invention is that of providing an improved cooling device for a lithography apparatus, a corresponding lithography apparatus and a method for operating a cooling device of a lithography apparatus.

According to a first aspect, a cooling device is proposed for cooling a position-sensitive component of a lithography apparatus. The cooling device comprises:
a cooling line having a liquid space for transporting a cooling liquid to the position-sensitive component and a gas space for receiving a gas, and
an elastic separation membrane arranged within the cooling line and serving to separate the gas space from the liquid space.

Pressure fluctuations in the cooling liquid can be dampened by introducing a compressible gas volume within the cooling line. This may significantly reduce a propagation of pressure fluctuations via the cooling liquid. In particular, the elastic separation membrane is configured to deform and thereby change a volume of the liquid space at the expense of a volume of the gas space.

For example, as seen in the cross section of the cooling line, an increase in pressure of the cooling liquid leads to a deformation of the separation membrane into the original gas space, and so the volume of the liquid space increases and the volume of the gas space decreases accordingly at the same time. Hence, an increase in pressure of the cooling liquid may be dampened by expanding the liquid in the liquid space and compressing the gas in the gas space.

Something analogous happens in the event of a reduction in the pressure of the cooling liquid in the liquid space of the cooling line, leading to an increase in the volume of the gas space. This allows the gas in the gas space to expand, and the cooling liquid in the liquid space is compressed, whereby the reduction in the pressure of the cooling liquid is dampened.

Accordingly, periodic pressure fluctuations of the cooling liquid may also be dampened with the aid of the compressible gas volume.

The position-sensitive component of the lithography apparatus may be an optical or a mechanical component of the lithography apparatus, e.g. a projection optical unit of the lithography apparatus. In particular, the position-sensitive component is a component part that must be kept at an exact position with only small tolerances during operation of the lithography apparatus.

The position-sensitive component of the lithography apparatus is for example a mirror of the lithography apparatus, e.g. a mirror of the projection optical unit of the lithography apparatus. The mirrors of a projection optical unit of an EUV lithography apparatus are usually movably attached to a force frame with actuators in order to be able to precisely adapt a position of the respective mirror.

The position-sensitive component of the lithography apparatus may also be a frame structure that serves as (e.g. optical) reference. The position-sensitive component may for example be a sensor frame of the lithography apparatus, e.g. of the projection optical unit of the lithography apparatus. A sensor frame usually comprises a sensor device for measuring a current position of one or more optical components of the lithography apparatus relative to the sensor frame. The sensor frame is for example mounted so as to be vibration-decoupled from a force frame of the optical component(s). The sensor device comprises e.g. one or more sensors, for example interferometers and/or other measuring devices for capturing a position of the optical component(s). The optical component(s) may for example comprise reflector elements for reflecting a light (e.g. laser light) transmitted by the sensors. For example, the one or more sensors serve to capture a position of the optical component(s) in six degrees of freedom. The six degrees of freedom comprise in particular three degrees of translation freedom (e.g. in three mutually perpendicular spatial directions) and three degrees of rotation freedom (e.g. with respect to a rotation about the three mutually perpendicular spatial directions).

The proposed cooling device with the compressible gas volume integrated in the cooling line allows pressure fluctuations in the cooling liquid to be dampened and a transmission to the position-sensitive component to be reduced or prevented. Consequently, a greater precision of the position and hence of the optical properties or of the reference properties of the position-sensitive component can be achieved. Consequently, an imaging property of the lithography apparatus may be improved. In addition, disturbance excitation can be better compensated, even in increasingly complex lithography apparatuses with an increasing number of disturbance sources.

For example, the lithography apparatus is an EUV or a DUV lithography apparatus. As noted above, EUV stands for “extreme ultraviolet” and refers to a wavelength of the operating light in the range from 0.1 nm to 30 nm, in particular 13.5 nm. DUV stands for “deep ultraviolet” and refers to a wavelength of the operating light between 30 nm and 250 nm.

The EUV or DUV lithography apparatus comprises an illumination system and a projection system. In particular, using the EUV or DUV lithography apparatus, the image of a mask (reticle) illuminated by the illumination system is projected by the projection system onto a substrate, for example a silicon wafer, which is coated with a light-sensitive layer (photoresist) and arranged in the image plane of the projection system, in order to transfer the mask structure to the light-sensitive coating of the substrate.

For example, the cooling line is a pipeline for passing through the cooling liquid. For example, the cooling line comprises a metal pipe and/or a stainless-steel pipe. For example, the cooling line may have a circular cross section. The cooling liquid is or contains water, for example. For example, the cooling line serves to transport the cooling liquid to and/or from the position-sensitive component. For example, the cooling line serves to transport the cooling liquid from a cooling unit of the cooling device to the position-sensitive component and/or from the position-sensitive component (back) to the cooling unit. The cooling device may also comprise more than one cooling line.

In particular, the cooling device serves to prevent high temperatures and temperature fluctuations of the position-sensitive component.

Especially mirrors of an EUV lithography apparatus (as an example for position-sensitive components) heat up as a result of an absorption of the high-energy EUV radiation. High temperatures and temperature fluctuations in the mirror caused thereby and the accompanying thermal deformation of the mirror may lead to wavefront aberrations and hence adversely affect the imaging properties of the mirrors. Mirrors of the lithography apparatus may be actively cooled in order to prevent thermally induced deformations.

The cooling device may also serve (in addition or instead) to cool for example a sensor frame (as an example of a position-sensitive component). This may prevent heating of the sensor frame due to thermal radiation. Thermal radiation is caused in particular by operating light of the lithography apparatus absorbed by mirror surfaces or structural elements. Actuators and heater heads, for example, may be further heat sources. The cooling device may help create a stable temperature environment for the sensor frame. As a result, a position measurement of the mirror or the plurality of mirrors with the aid of the sensor device held by the sensor frame may be performed with a greater accuracy.

The cooling device furthermore comprises, for example, a cooling unit for cooling the cooling liquid, one or more pumps for creating a required coolant flow rate of the cooling liquid, and one or more valves for controlling the cooling flow.

A specific coolant flow rate is required for cooling and realized with of a pump system. This results in dynamic disturbance excitation, as each pump creates local pressure fluctuations. These are transmitted through the entire cooling circuit with a coolant sound (water-borne sound, longitudinal water-borne sound wave). Furthermore, any cross-sectional change and any deflection of the liquid line, and any built-in valve of the cooling circuit, may constitute a source of disturbance that causes local pressure fluctuations of the liquid. This type of dynamic disturbance excitation is also referred to as flow-induced vibrations (FIV). Water-borne sound transmits the disturbance excitation to the cooled position-sensitive component. This causes the position of the position-sensitive component to deviate from a target position. In particular, a pressure surge of the cooling liquid acts on surfaces of the cooled position-sensitive component. The pressure surge is converted into a force at the surfaces on which it acts. This force leads to a deviation of the position of the position-sensitive component from the target position.

The liquid space of the cooling line is arranged in the interior of the cooling line and serves to allow the cooling liquid to flow therethrough. Furthermore, the gas space is arranged in the interior of the cooling line and serves to receive a gas. Volumes of the liquid space and of the gas space are variable on account of the elastic separation membrane, which separates the liquid space from the gas space. As a result, a volume of the cooling liquid and a volume of the gas are variable on account of the elastic separation membrane.

When the cooling device is in operation, e.g. when the lithography apparatus is in operation, the liquid space, as seen in the cross section of the cooling line, is for example completely filled with the cooling liquid. Furthermore, the gas space, as seen in the cross section of the cooling line, is for example completely filled with the gas.

The elastic separation membrane is configured in particular to form a gas bubble together with a gas received in the gas space. For example, the gas bubble is an axial gas bubble with respect to a central longitudinal axis of the liquid line.

The elastic separation membrane is in particular (reversibly) deformable in order to adapt the volume of the liquid space and hence of the cooling liquid to a pressure of the cooling liquid in the liquid space.

For example, the elastic separation membrane is liquid-tight and/or gas-tight.

For example, the elastic separation membrane comprises an (e.g. thin-walled) elastic material. A material of the elastic separation membrane for example contains polyurethane, silicone, unvulcanized rubber, vulcanized rubber, natural rubber, silicone rubber, fluororubber and/or another elastic material. Due to its aging resistance and low outgassing, fluororubber is particularly well suited for use in vacuum. A material of the elastic separation membrane may for example also contain a fluorothermoplastic, such as tetrafluoroethylene, hexafluoropropylene and/or vinylidene fluoride.

As a result of the elastic material (e.g. a highly damped polymer), a further damping of pressure fluctuations of the cooling liquid may be provided in addition to the compression of the gas volume separated therewith.

The gas space may be a closed gas space for receiving a gas in a static state. In an alternative to that, the gas space may also be part of a gas circuit, in which the gas flows through the gas space during operation. For example, a gas flow may be realized with the aid of a gas pump in this case.

For example, the gas is a gas containing air, high purity room air, helium and/or one or more noble gases.

In embodiments, the cooling device comprises a gas that is received in the gas space. For example, the gas space in these embodiments is a sealed gas space in which the gas remains (e.g. permanently).

In embodiments, the cooling line with the integrated gas volume is configured to damp and/or suppress pressure fluctuations of the cooling liquid in a frequency range of 1 to 2 kHz, 1 to 1 kHz, 1 to 800 Hz, 1 to 500 Hz, 1 to 400 Hz, 1 to 200 Hz, 1 to 100 Hz and/or 50 to 150 Hz.

According to one embodiment, the elastic separation membrane is a pressure membrane that is configured to deform in the event of a change in pressure of the cooling liquid such that a volume of the gas space changes accordingly.

In particular, in the event of a change in pressure of the cooling liquid, the separation membrane deforms according to the change in pressure. As a result, the gas in the gas space is compressed or expands in particular.

As seen in the cross section of the cooling line, the gas space separated by the elastic separation membrane is rotationally symmetric according to a further embodiment.

On account of a rotationally symmetric embodiment of the gas space and hence of the gas volume, all forces acting on the gas bubble that is formed by the separation membrane and the gas in the gas space balance, and a force-free system is present.

As seen in the cross section of the cooling line, the liquid space and the gas space that is separated from the liquid space with the elastic separation membrane are arranged coaxially according to a further embodiment.

This allows even better damping of a pressure fluctuation by the gas volume.

As seen in the cross section of the cooling line and in relation to the liquid space, the gas space is an interior gas space or an exterior gas space according to a further embodiment.

The advantage of an interior gas space and hence of an interior compressible gas volume is that the gas volume is arranged where the highest flow speed of the cooling liquid occurs. Hence, damping of pressure fluctuations in the cooling liquid is particularly effective.

The advantage of an exterior gas space is that the gas space is more easily accessible from the outside, and hence the gas can be filled and/or refilled more easily. For example, the gas may be guided into the gas space via an opening and/or a valve in a wall of the cooling line.

In an interior gas space, the gas space is delimited for example exclusively by the separation membrane and not by an inner wall of the cooling line.

In an exterior gas space, the gas space is delimited for example both by the separation membrane and by an inner wall of the cooling line.

According to a further embodiment, the cooling device comprises an elastic tube that comprises the elastic separation membrane and serves to form the gas space.

This makes it particularly easy to realize a gas volume integrated into a cooling line.

For example, the gas space is formed inside the tube (an example of an interior gas space). Then the liquid space is formed accordingly outside the tube (e.g. between an outer side of the tube and an inner wall of the cooling line).

In an alternative to that, the gas space may for example also be formed outside the tube (e.g. between an outer side of the tube and an inner wall of the cooling line) (an example of an exterior gas space). Then the liquid space is formed accordingly within the tube.

According to a further embodiment, the cooling device comprises at least one spacer arranged between the elastic separation membrane and an inner wall of the cooling line.

An arrangement of the elastic separation membrane within the cooling line may be improved by the at least one spacer, for example also during the operation of the cooling device. For example, a movement of the elastic separation membrane within the cooling line may be restricted (but without restricting a deformation of the elastic separation membrane), in particular during the operation of the cooling device. For example, there might be limits on a position of the gas space relative to the liquid space. For example, a rotationally symmetric and/or coaxial arrangement of the gas space relative to the liquid space might also be (e.g. substantially) maintained during operation.

The at least one spacer is for example arranged in the gas space or in the liquid space.

The cooling device may also comprise a plurality of spacers. The plurality of spacers may be arranged (e.g. radially) at one longitudinal position of the cooling line and/or (e.g. spaced apart) at plurality of longitudinal positions of the cooling line.

According to a further embodiment, the cooling device comprises a plurality of spacers that are formed by nubs arranged on an outer side of the elastic separation membrane.

The nubs (e.g. projections) protrude from an outer side of the elastic separation membrane in particular, e.g. in the direction of the inner wall of the cooling line and/or in a radial direction of the cooling line. For example, the nubs might be formed from the same material as the separation membrane. For example, the separation membrane may also be produced in one piece with the nubs.

According to a further embodiment, the cooling device comprises a securing element for attaching the elastic separation membrane to an inner wall of the cooling line.

This allows a position of the separation membrane to be restricted and/or fixed within the cooling line. For example, the securing element may also comprise or form the at least one spacer.

According to a further embodiment, the cooling device comprises equipment for setting a pressure of a gas in the gas space.

This allows a gas pressure (preload pressure) of a gas in the gas space and hence a damping frequency of the gas volume to be set in a targeted manner. In particular, the set gas pressure is a gas pressure in a rest state (i.e. an undeformed state) of the separation membrane. A damping effect of the gas volume depends in particular on a relative pressure between the gas pressure in the gas volume and a pressure of the liquid.

According to a further embodiment, the cooling device comprises two or more elastic separation membranes that are arranged within the cooling line and correspondingly form two or more gas spaces that are separated from one another and from the liquid space.

Pressure fluctuations may be dampened in an even more targeted manner by providing a plurality of separate (e.g. closed) gas spaces and hence gas volumes. For example, a gas pressure of a gas may differ in the plurality of gas spaces, and so pressure surges at different frequencies can be dampened.

For example, gas spaces and hence gas volumes may also be designed in a targeted manner for individual position-sensitive components. For example, a gas pressure of a gas in a respective gas space may be set in a targeted manner for the damping of a disturbance excitation of a respective position-sensitive component. For example, a respective gas space may be arranged adjacent to and, in relation to a flow direction (direction of flow) of the cooling liquid, (e.g. immediately) upstream of a respective position-sensitive component.

According to a further embodiment, as seen in the cross section of the cooling line, the two or more gas spaces are separated from one another and from the liquid space, and/or
in relation to a flow direction of the cooling liquid, the two or more gas spaces are separated from one another and from the liquid space.

According to a further embodiment, in relation to a flow direction of the cooling liquid, the two or more gas spaces are separated from one another and from the liquid space, the cooling device has a gas in each of the two or more gas spaces, and the respective gases have mutually differing pressures.

For example, the cooling device comprises one or more pieces of equipment configured to set a pressure of a gas in the respective gas space. For example, this allows a gas pressure and hence a damping frequency to be set in a targeted manner in each gas space.

According to a further embodiment, the cooling device comprises a foam-like and/or sponge-like element with a plurality of bubbles and an elastic material surrounding the plurality of bubbles, wherein the gas space is formed by the plurality of bubbles of the foam-like and/or sponge-like element, and the separation membrane is formed by the elastic material that surrounds the plurality of bubbles.

The gas space separated by the separation membrane may be provided in an alternative manner as a result of the foam-like and/or sponge-like element.

According to a further embodiment, the cooling device is configured such that a cooling liquid flows through the cooling line in a flow direction, and a diameter of the cooling line is tapered in the flow direction.

As a result of this modified shape of the cooling line, the flow velocity of the cooling liquid may be influenced, and hence a frequency range of the damping may be set.

For example, the diameter of the cooling line tapers uniformly in the flow direction.

For example, the cooling line extends (e.g. linearly) in a longitudinal direction, and the cooling liquid flows through the cooling line in the longitudinal direction. For example, the diameter of the cooling line tapers in the longitudinal direction. In an alternative to that, the cooling line may also be curved, e.g. also extend helically (often also referred to as spirally). For example, the diameter of the cooling line tapers along the helically curved cooling line.

According to a second aspect, a lithography apparatus, in particular an EUV lithography apparatus, is proposed. The lithography apparatus comprises a cooling device as described above.

The lithography apparatus for example comprises at least one position-sensitive component.

According to a third aspect, a method for operating a cooling device is proposed. The cooling device serves to cool a position-sensitive component of a lithography apparatus. The cooling device comprises a cooling line having a liquid space for transporting a cooling liquid to the position-sensitive component and a gas space for receiving a gas, and an elastic separation membrane arranged within the cooling line and serving to separate the gas space from the liquid space. The method comprises the steps of:
a) allowing a cooling liquid to flow through the liquid space of the cooling line, and
b) changing a volume of the liquid space by deforming the elastic separation membrane in response to a change in pressure of the cooling liquid in the liquid space.

Changing a volume of the liquid space means in particular a change in a volume of the cooling liquid in the liquid space.

The position-sensitive component is preferably a position-sensitive component of a projection optical unit of the lithography apparatus (projection exposure apparatus). However, the position-sensitive component may also be a position-sensitive component of an illumination system of the lithography apparatus.

According to a fourth aspect, a temperature-control device for controlling the temperature of a position-sensitive component of a lithography apparatus is proposed. The temperature-control device comprises:
a liquid line having a liquid space for transporting a temperature-control liquid to the position-sensitive component and a gas space for receiving a gas, and
an elastic separation membrane arranged within the liquid line and serving to separate the gas space from the liquid space.

The temperature-control device may be used to influence a thermal condition of the position-sensitive component. In particular, the position-sensitive component can be temperature-controlled, i.e. cooled or heated, with the aid of the temperature-control device. Accordingly, the temperature-control device is a cooling device or a heating device. Furthermore, the temperature-control liquid is accordingly a cooling liquid or a heating liquid.

To the extent that the present application makes reference to a cooling device, cooling, cooling liquid, cooling line, method for operating a cooling device, etc., a heating device, heating, heating liquid, heating line, method for operating a heating device, etc. may also be used accordingly.

“A(n)” should not necessarily be understood as a restriction to exactly one element in the present case. Rather, there may also be a plurality of elements, such as two, three or more. Any other numeral used here should also not be understood as restrictive to exactly the stated number of elements. Rather, numerical deviations upward and downward are possible, unless otherwise indicated.

The embodiments and features described for the cooling device (first aspect) correspondingly apply to the further aspects (second, third and fourth aspect), and vice versa.

Further feasible implementations of the invention also comprise non-explicitly mentioned combinations of features or embodiments described hereinabove or hereinafter with regard to the exemplary embodiments. A person skilled in the art will also add individual aspects as improvements or supplementations to the respective basic form of the invention.

Further advantageous embodiments and aspects of the invention are the subject matter of the dependent claims and of the exemplary embodiments of the invention described below. The invention will be explained in detail hereinafter on the basis of preferred embodiments with reference to the appended figures.

### BRIEF DESCRIPTION OF THE DRAWINGS

FIG. 1 shows a schematic meridional section of a projection exposure apparatus for EUV projection lithography;

FIG. 2 shows a positioning system having an optical component of the projection exposure apparatus from FIG. 1 according to an embodiment;

FIG. 3 shows a cooling device for cooling the optical component from FIG. 2 according to an embodiment, wherein the cooling device comprises cooling line equipment with an integrated compressible gas volume;

FIG. 4 shows a cross-sectional view of a functional principle of the cooling line equipment from FIG. 3;

FIG. 5 shows a cross-sectional view of the cooling line equipment from FIG. 3, wherein an elastic separation membrane of the cooling line equipment is in a rest state;

FIG. 6 shows a view similar to FIG. 5, wherein the elastic separation membrane is in an elastically deformed state;

FIG. 7 shows a cross-sectional view of a further embodiment of the cooling line equipment of the cooling device from FIG. 3;

FIG. 8 shows a cross-sectional view of a further embodiment of the cooling line equipment of the cooling device from FIG. 3;

FIG. 9 shows a cross-sectional view of a further embodiment of the cooling line equipment of the cooling device from FIG. 3;

FIG. 10 shows a cross-sectional view of a further embodiment of the cooling line equipment of the cooling device from FIG. 3, wherein the separation membrane of the cooling line equipment comprises spacers;

FIG. 11 shows a perspective view of a further embodiment of the cooling line equipment of the cooling device from FIG. 3, wherein the cooling line equipment comprises a securing element according to a first variant;

FIG. 12 shows a perspective view of a further embodiment of the cooling line equipment of the cooling device from FIG. 3, wherein the cooling line equipment comprises a securing element according to a second variant;

FIG. 13 shows a cross-sectional view of a further embodiment of the cooling line equipment of the cooling device from FIG. 3;

FIG. 14 shows a side view of a further embodiment of the cooling line equipment of the cooling device from FIG. 3;

FIG. 15 shows a side view of a further embodiment of the cooling line equipment of the cooling device from FIG. 3; and

FIG. 16 shows a flowchart of a method for operating a cooling device of a projection exposure apparatus, according to one embodiment.

### DETAILED DESCRIPTION

Unless indicated to the contrary, elements that are identical, analogous, or functionally so have been provided with the same reference signs in the figures. It should also be noted that the illustrations in the figures are not necessarily to scale.

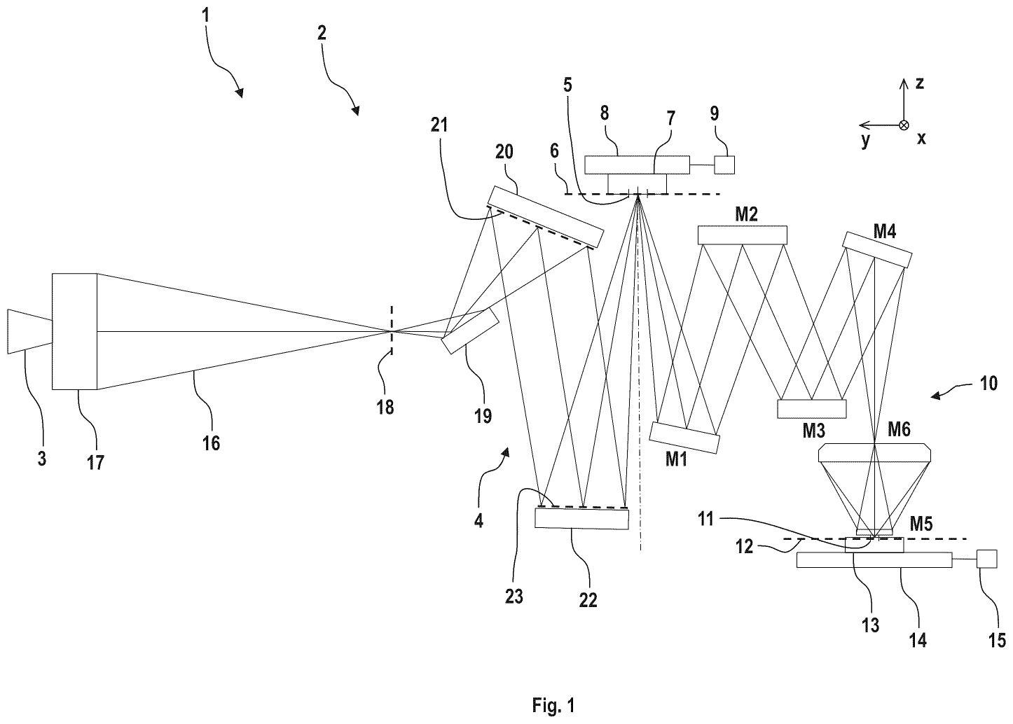

FIG. 1 shows one embodiment of a projection exposure apparatus 1 (lithography apparatus), in particular an EUV lithography apparatus. One embodiment of an illumination system 2 of the projection exposure apparatus 1 has, in addition to a light or radiation source 3, an illumination optical unit 4 for illuminating an object field 5 in an object plane 6. In an alternative embodiment, the light source 3 may also be provided as a module separate from the rest of the illumination system 2. In this case, the illumination system 2 does not include the light source 3.

A reticle 7 arranged in the object field 5 is exposed. The reticle 7 is held by a reticle holder 8. The reticle holder 8 is displaceable by a reticle displacement drive 9, in particular in a scanning direction.

FIG. 1 shows, by way of illustration, a Cartesian coordinate system with an x-direction x, a y-direction y, and a z-direction z. The x-direction x runs perpendicularly into the plane of the drawing. The y-direction y runs horizontally, and the z-direction z runs vertically. The scanning direction runs in the y-direction y in FIG. 1. The z-direction z runs perpendicularly to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6. In an alternative, an angle that differs from 0° between the object plane 6 and the image plane 12 is also feasible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable with a wafer displacement drive 15, in particular in the y-direction y. The displacement on the one hand of the reticle 7 with the reticle displacement drive 9 and on the other hand with the wafer 13 via the wafer displacement drive 15 may be implemented synchronously with each other.

The light source 3 is an EUV radiation source. The light source 3 emits in particular EUV radiation 16, which is also referred to below as used radiation, illumination radiation or illumination light. The used radiation 16 has in particular a wavelength in the range between 5 nm and 30 nm. The light source 3 may be a plasma source, for example an LPP (laser produced plasma) source or a GDPP (gas discharge produced plasma) source. It may also be a synchrotron-based radiation source. The light source 3 may be a free electron laser (FEL).

The illumination radiation 16 emanating from the light source 3 is focused by a collector 17. The collector 17 may be a collector with one or more ellipsoidal and/or hyperboloidal reflection surfaces. The illumination radiation 16 may be incident on the at least one reflection surface of the collector 17 with grazing incidence (GI), i.e. at angles of incidence of greater than 45°, or with normal incidence (NI), i.e. at angles of incidence of less than 45°. The collector 17 may be structured and/or coated, both to optimize its reflectivity for the used radiation and to suppress extraneous light.

The illumination radiation 16 propagates through an intermediate focus in an intermediate focal plane 18 downstream of the collector 17. The intermediate focal plane 18 may represent a separation between a radiation source module, comprising the light source 3 and the collector 17, and the illumination optical unit 4.

The illumination optical unit 4 comprises a deflection mirror 19 and, arranged downstream thereof in the beam path, a first facet mirror 20. The deflection mirror 19 may be a plane deflection mirror or, in an alternative to that, a mirror with a beam-influencing effect going beyond the pure deflection effect. In an alternative to that or in addition, the deflection mirror 19 may be in the form of a spectral filter that separates a used light wavelength of the illumination radiation 16 from extraneous light at a different wavelength. If the first facet mirror 20 is arranged in a plane of the illumination optical unit 4 which is optically conjugate to the object plane 6 as a field plane, then this facet mirror is also referred to as a field facet mirror. The first facet mirror 20 comprises a multiplicity of individual first facets 21, which may also be referred to as field facets. Only some of these first facets 21 are shown in FIG. 1 by way of example.

The first facets 21 may take the form of macroscopic facets, in particular as rectangular facets or as facets with an arc-shaped or part-circular edge contour. The first facets 21 may take the form of plane facets or, in an alternative to that, convexly or concavely curved facets.

As is known for example from DE 10 2008 009 600 A1, the first facets 21 themselves may each also be composed of a multiplicity of individual mirrors, in particular a multiplicity of micromirrors. The first facet mirror 20 may take the form of a microelectromechanical system (MEMS system) in particular. For details, reference is made to DE 10 2008 009 600 A1.

The illumination radiation 16 propagates horizontally, i.e. in the y-direction y, between the collector 17 and the deflection mirror 19.

In the beam path of the illumination optical unit 4, a second facet mirror 22 is disposed downstream of the first facet mirror 20. If the second facet mirror 22 is arranged in a pupil plane of the illumination optical unit 4, it is also referred to as a pupil facet mirror. The second facet mirror 22 may also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 may likewise be macroscopic facets, which may for example have a round, rectangular or else hexagonal boundary, or alternatively may be facets composed of micromirrors. For details, reference is also made to DE 10 2008 009 600 A1.

The second facets 23 may have plane reflection surfaces or, in an alternative to that, convexly or concavely curved reflection surfaces.

The illumination optical unit 4 thus forms a doubly faceted system. This fundamental principle is also referred to as a fly's eye integrator.

It may be advantageous to arrange the second facet mirror 22 not exactly in a plane that is optically conjugate to a pupil plane of the projection optical unit 10. In particular, the second facet mirror 22 may be arranged so as to be tilted in relation to a pupil plane of the projection optical unit 10, as described for example in DE 10 2017 220 586 A1.

The second facet mirror 22 is used to image the individual first facets 21 into the object field 5. The second facet mirror 22 is the last beam-shaping mirror or actually the last mirror for the illumination radiation 16 in the beam path upstream of the object field 5.

In a further embodiment (not illustrated) of the illumination optical unit 4, a transfer optical unit contributing in particular to the imaging of the first facets 21 into the object field 5 may be arranged in the beam path between the second facet mirror 22 and the object field 5. The transfer optical unit may have exactly one mirror or, in an alternative to that, two or more mirrors, which are arranged one behind another in the beam path of the illumination optical unit 4. The transfer optical unit may in particular comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the first facet mirror 20, and the second facet mirror 22.

In a further embodiment of the illumination optical unit 4, the deflection mirror 19 may also be omitted, and so downstream of the collector 17 the illumination optical unit 4 may then have exactly two mirrors, specifically the first facet mirror 20 and the second facet mirror 22. The imaging of the first facets 21 into the object plane 6 by the second facets 23, or with the second facets 23 and transfer optics is generally only an approximate imaging.

The projection optical unit 10 comprises a plurality of mirrors Mi, which are consecutively numbered in accordance with their arrangement in the beam path of the projection exposure apparatus 1.

In the example illustrated in FIG. 1, the projection optical unit 10 comprises six mirrors M1 to M6. Alternatives with four, eight, ten, twelve or any other number of mirrors Mi are likewise feasible. The projection optical unit 10 is a doubly obscured optical unit. The penultimate mirror M5 and the last mirror M6 each have a passage opening for the illumination radiation 16. The projection optical unit 10 has an image-side numerical aperture that is greater than 0.5 and may also be greater than 0.6 and may be, for example, 0.7 or 0.75.

Reflection surfaces of the mirrors Mi may be in the form of free-form surfaces without an axis of rotational symmetry. In an alternative to that, the reflection surfaces of the mirrors Mi may be designed as aspherical surfaces with exactly one axis of rotational symmetry of the reflection surface shape. Just like the mirrors of the illumination optical unit 4, the mirrors Mi may have highly reflective coatings for the illumination radiation 16. These coatings may take the form of multilayer coatings, in particular with alternating layers of molybdenum and silicon.

The projection optical unit 10 has a large object-image offset in the y-direction y between a y-coordinate of a center of the object field 5 and a y-coordinate of the center of the image field 11. This object-image offset in the y-direction y may be of approximately the same magnitude as a z-distance between the object plane 6 and the image plane 12.

In particular, the projection optical unit 10 may have an anamorphic design. It has in particular different imaging scales βx, βy in the x- and y-directions x, y. The two imaging scales βx, βy of the projection optical unit 10 are preferably (βx, βy)=(+/−0.25, +/−0.125). A positive imaging scale β means imaging without image inversion. A negative sign for the imaging scale β means imaging with image inversion.

The projection optical unit 10 consequently leads to a reduction in size with a ratio of 4:1 in the x-direction x, i.e. in a direction perpendicular to the scanning direction.

The projection optical unit 10 leads to a reduction in size with a ratio of 8:1 in the y-direction y, i.e. in the scanning direction.

Other imaging scales are likewise feasible. Imaging scales with the same sign and the same absolute value in the x-direction x and y-direction y are also possible, for example with absolute values of 0.125 or of 0.25.

The number of intermediate image planes in the x-direction x and in the y-direction y in the beam path between the object field 5 and the image field 11 may be the same or may differ, depending on the embodiment of the projection optical unit 10. Examples of projection optical units with different numbers of such intermediate images in the x-direction x and y-direction y are known from US 2018/0074303 A1.

In each case, one of the second facets 23 is assigned to exactly one of the first facets 21 for forming in each case an illumination channel for illuminating the object field 5. This can yield in particular illumination according to the Köhler principle. The far field is decomposed into a multiplicity of object fields 5 with the aid of the first facets 21. The first facets 21 create a plurality of images of the intermediate focus on the second facets 23 respectively assigned to them.

The first facets 21 are each imaged onto the reticle 7 and overlaid over one another by an associated second facet 23 for the purpose of illuminating the object field 5. The illumination of the object field 5 is in particular as homogeneous as possible. It preferably has a uniformity error of less than 2%. Field uniformity may be achieved by superposing different illumination channels.

The illumination of the entrance pupil of the projection optical unit 10 may be defined geometrically by an arrangement of the second facets 23. The intensity distribution in the entrance pupil of the projection optical unit 10 may be set by selecting the illumination channels, in particular the subset of the second facets 23, which guide light. This intensity distribution is also referred to as illumination setting or illumination pupil filling.

A likewise preferred pupil uniformity in the region of sections of an illumination pupil of the illumination optical unit 4 that are illuminated in a defined manner may be achieved by a redistribution of the illumination channels.

Further aspects and details of the illumination of the object field 5 and in particular of the entrance pupil of the projection optical unit 10 are described below.

The projection optical unit 10 may have a homocentric entrance pupil in particular. The latter may be accessible. It may also be inaccessible.

The entrance pupil of the projection optical unit 10 regularly cannot be exactly illuminated with the second facet mirror 22. In the case of an imaging process of the projection optical unit 10 that images the center of the second facet mirror 22 telecentrically onto the wafer 13, the aperture rays often do not intersect at a single point. However, it is possible to find an area in which the spacing of the aperture rays that is determined in pairs becomes minimal. This area represents the entrance pupil or an area conjugate thereto in real space. In particular, this area exhibits a finite curvature.

It may be the case that the projection optical unit 10 has different positions of the entrance pupil for the tangential beam path and for the sagittal beam path. In this case, an imaging element, in particular an optical structural element of the transfer optical unit, should be provided between the second facet mirror 22 and the reticle 7. The different positions of the tangential entrance pupil and the sagittal entrance pupil may be taken into account with this optical element.

In the arrangement of the components of the illumination optical unit 4 illustrated in FIG. 1, the second facet mirror 22 is arranged in an area conjugate to the entrance pupil of the projection optical unit 10. The first facet mirror 20 is in a tilted arrangement in relation to the object plane 6. The first facet mirror 20 is in a tilted arrangement in relation to an arrangement plane defined by the deflection mirror 19. The first facet mirror 20 is arranged with a tilt in relation to an arrangement plane defined by the second facet mirror 22.

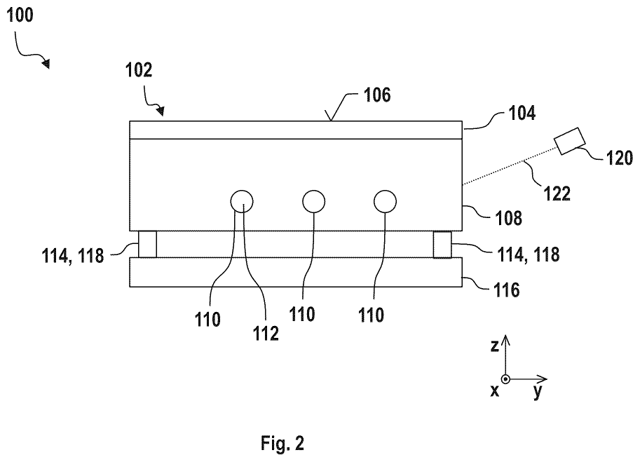

FIG. 2 shows a positioning system 100 having an optical component 102 (as an example of a position-sensitive component) according to one embodiment.

The optical component 102 is for example a mirror of the projection exposure apparatus 1 (lithography apparatus), in particular of the projection optical unit 10, from FIG. 1. For example, the optical component 102 is one of the mirrors M1-M6. In the following, the optical component 102 is described as a mirror; however, it may also be an optical component other than a mirror in other examples.

As shown in FIG. 2, the mirror 102 comprises a coating 104 with an optically active surface 106. The mirror 102 also comprises a substrate 108. Cooling lines 110, through which a cooling liquid 112 such as water is guided in order to actively cool the mirror 102, are arranged in the substrate 108. A cooling of the mirror 102 serves to prevent thermal deformations of the mirror 102, even in the event of high-energy EUV radiation 16 (FIG. 1) being radiated thereon.

The mirror 102 is movably attached to a force frame 116 through actuator equipment 114. The actuator equipment 114 for example comprises a plurality of actuators 118 and a drive unit (not shown). The actuator equipment 114 for example serves to position the mirror 102 in relation to six degrees of freedom (translation in the X-, Y- and Z-direction and rotation about the X-, Y- and Z-direction).

The positioning system 100 furthermore comprises sensor equipment 120 for capturing a current position of the mirror 102. The sensor equipment 120 is only schematically indicated in FIG. 2. The sensor equipment 120 comprises one or more sensors, such as interferometers. The sensors of the sensor equipment 120 are for example attached to a sensor frame (not shown). The sensor frame is for example attached to the force frame 116 in a vibration-decoupled manner. For example, a current position of the mirror 102 is captured via laser beams 122.

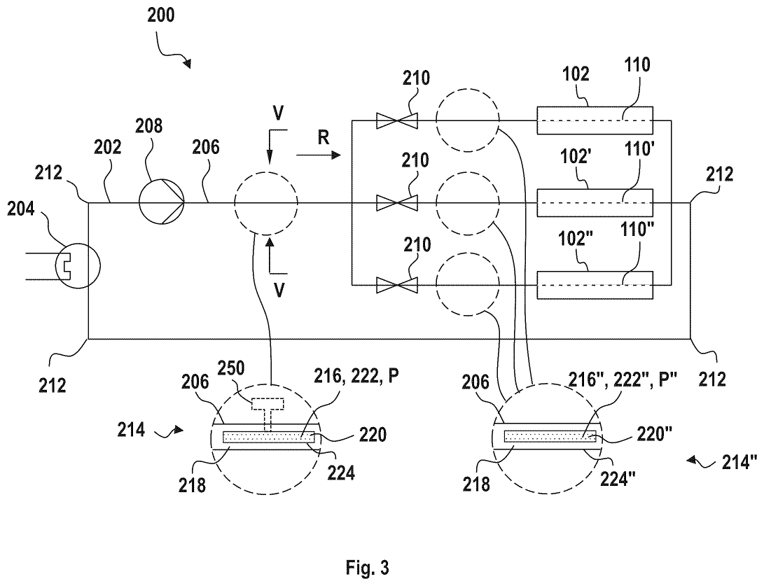

FIG. 3 shows a cooling device 200 for cooling the mirror 102. The cooling device comprises a cooling circuit 202. The cooling device 200 comprises a cooling unit 204 for cooling a cooling liquid 112 (FIG. 2) and cooling lines 206, 110 for transporting the cooling liquid 112. The cooling device 200 moreover comprises one or more pumps 208 for creating a required coolant flow rate of the cooling liquid 112. The cooling device 200 furthermore comprises one or more valves 210 for controlling the cooling flow. The cooling device 200 may serve to cool a plurality of components of the lithography apparatus 1. By way of example, the mirror 102 from FIG. 2 is drawn as a cooled component in FIG. 3. The cooling lines 110 (FIG. 2), which are arranged in the mirror substrate 108, are drawn schematically in FIG. 3. Furthermore, two further mirrors 102′ and 102″—similar to the mirror 102 from FIG. 2—are shown by way of example in FIG. 3 as further cooled components.

Pumps of the cooling device 200, such as the pump 208, cause local pressure fluctuations in the liquid 112, whereby a dynamic disturbance excitation is created. These pressure fluctuations are transmitted via a longitudinal water-borne sound wave through the entire cooling circuit 202. Furthermore, cross-sectional changes (not shown) of the cooling line 206, deflections 212 of the cooling line 206 and valves 210 of the cooling device 200 may also represent sources of disturbance that cause local pressure fluctuations of the liquid 112. Such an acoustic disturbance excitation is transmitted to the cooled optical component 102, 102′, 102″ (the mirror 102, 102′, 102″) through water-borne sound. This may lead to a change in position of the respective mirror 102, 102′, 102″, and so the actual position of the respective mirror 102, 102′, 102″ deviates from a target position.

In the example shown in FIG. 3 and the following description, the cooling device 200 serves to cool the mirrors 102, 102′, 102″ by way of example. In other examples, however, the cooling device 200 may also serve to cool other position-sensitive components, for example other mirrors and/or a sensor frame (not shown) of the projection exposure apparatus 1 (lithography apparatus).

In order to damp pressure fluctuations of the cooling liquid 112, the cooling device 200 comprises cooling line equipment 214 with an integrated compressible gas volume 216. In particular, the cooling line equipment 214 comprises the cooling line 206 or a portion of the cooling line 206, a liquid space 218 allowing the cooling liquid 112 to flow therethrough and a gas space 220 for receiving a gas 222 (gas volume 216). Furthermore, the cooling line equipment 214 comprises an elastic separation membrane 224 serving to separate the gas space 220 from the liquid space 218.

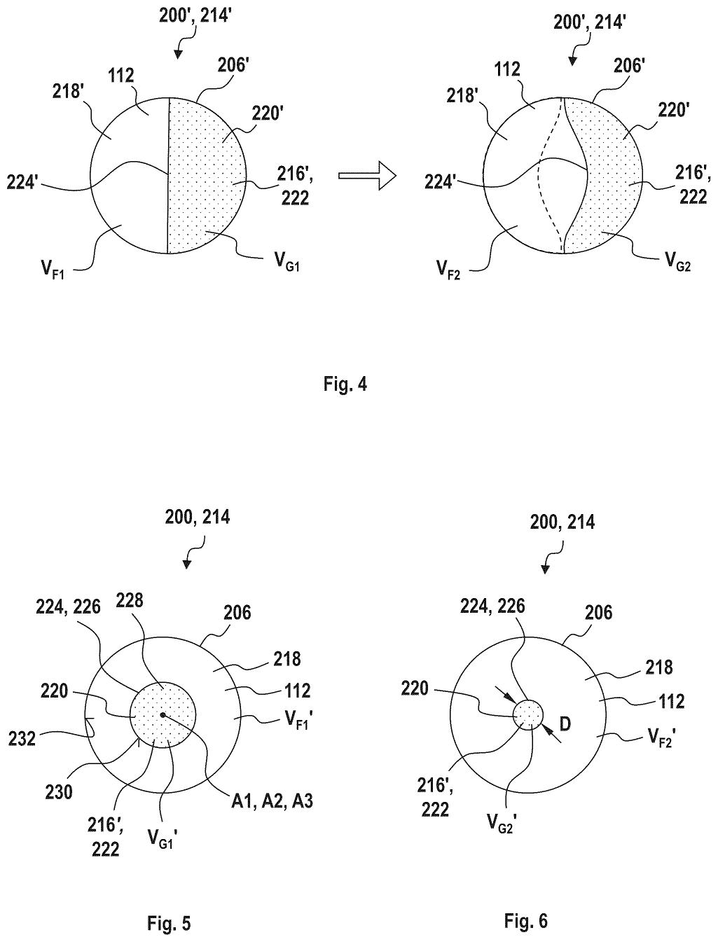

FIG. 4 illustrates a functional principle of the cooling line equipment 200′ from FIG. 3. The left-hand side of FIG. 4 shows cooling line equipment 214′ with a cooling line 206′ and an elastic separation membrane 224′, which is arranged in the cooling line 206′ and in a rest state. In particular, the elastic separation membrane 224′ on the left-hand side of FIG. 4 is in a relaxed, undeformed state. The elastic separation membrane 224′ separates the cooling liquid 112 in the liquid space 218′ from the gas 222 in the gas space 220′. A volume of cooling liquid 112 is in the rest state VF1, and a volume of gas 222 is in the rest state VG1.

The right-hand side of FIG. 4 shows the cooling line equipment 214′ with the elastic separation membrane 224′ in a state in which the elastic separation membrane 224′ is in an elastically deformed state. By increasing the pressure of the cooling liquid 112, the separation membrane 224′ was deformed such that the volume VF2 of the liquid space 218′ increased and the volume VG2 of the gas space 220′ decreased accordingly at the same time. Hence, an increase in pressure of the cooling liquid 112 may be dampened by expanding the liquid 112 and compressing the gas 222 in the gas space 220′.

A dashed line is used in FIG. 4 to illustrate a deformation of the separation membrane 224′ in the event of a reduction in pressure of the cooling liquid 112 in the liquid space 218′, which would lead to an increase in the volume of the gas space 220′. Accordingly, periodic pressure fluctuations of the cooling liquid 112 may also be dampened via compressible gas bubble 216′.

FIG. 5 shows a cross-sectional view of the cooling line equipment 214 from FIG. 3 along the line V-V. In this embodiment, the elastic separation membrane 224 is a tube 226, in the interior 228 of which the gas 220 is located. Hence, the gas space 220 is an interior gas space 220 in relation to the liquid space 218. The liquid space 218, through which the cooling liquid 112 flows, is formed between an outer wall 230 of the tube 226 and an inner wall 232 of the cooling line 206.

Furthermore, the gas space 220 is arranged and embodied in rotationally symmetric fashion with respect to the cooling line 206 in this embodiment. In particular, the gas space 220, the liquid space 218 and the cooling line 206 are arranged coaxially to one another. In FIG. 5, a central axis of the cooling line 206 is denoted by reference sign A1, a central axis of the liquid space 218 is denoted by reference sign A2, and a central axis of the gas space 220 is denoted by reference sign A3.

In FIG. 5, the elastic separation membrane 224 (i.e. the tube 226) is in a rest state. A volume of gas 222 is VG1′, and a volume of cooling liquid 112 is VF1′.

FIG. 6 shows the cooling line equipment 214 from FIG. 5, wherein the elastic separation membrane 224 is in an elastically deformed state. By increasing the pressure of the cooling liquid 112, the separation membrane 224 was deformed such that the volume VF2′ of the liquid space 218 increased and the volume VG2′ of the gas space 220 decreased accordingly at the same time. In particular, a diameter D of the tube 226 comprising the separation membrane 224 has reduced. On account of the rotational symmetry, the increase in pressure of the cooling liquid 112 acts uniformly on the tube 226. As a result, an increase in pressure of the cooling liquid 112 may be dampened well by compressing the gas 222 in the gas space 220.

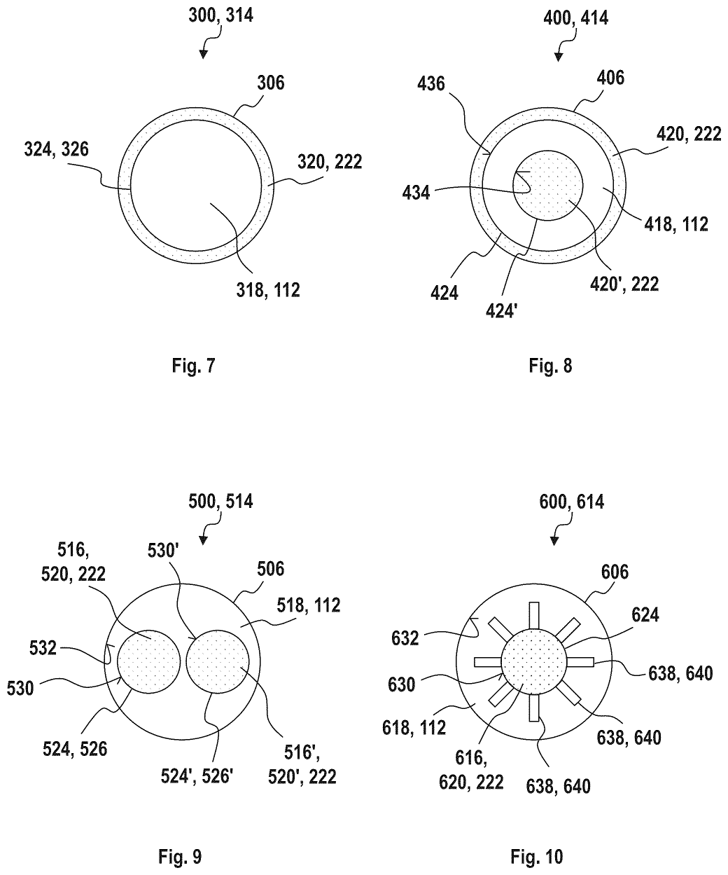

FIG. 7 shows a cross-sectional view of a further embodiment of cooling line equipment 314 of a cooling device 300 of the lithography apparatus 1. The cooling line equipment 314 comprises a cooling line 306 with an exterior gas space 320 in relation to a liquid space 318. In particular, a separation membrane 324 in this embodiment is embodied in the form of a tube 326. This is a further example of a rotationally symmetric gas space 220.

FIG. 8 shows a cross-sectional view of a further embodiment of cooling line equipment 414 of a cooling device 400 of the lithography apparatus 1. The cooling line equipment 414 comprises a cooling line 406 having two coaxially arranged separation membranes 424 and 424′. In other words, the two separation membranes 424 and 424′ are concentric as seen in the cross section of the cooling line 406. As seen in the cross section of the cooling line 406, three spaces that are separated from one another are obtained in this embodiment with the two separation membranes 424 and 424′: two gas spaces 420 and 420′ for receiving a gas 222 and a liquid space 418 for allowing the cooling liquid 112 to pass through. In particular, the ring-shaped liquid space 418 in cross section is in contact on both sides with a respective gas space 420 and gas space 420′ for pressure equalization, i.e. both on its inner side 434 and on its outer side 436.

In a variant of the embodiment of FIG. 8 (not shown here), a ring-shaped gas space may also be flanked by two liquid spaces.

FIG. 9 shows a cross-sectional view of a further embodiment of cooling line equipment 514 of a cooling device 500 of the lithography apparatus 1. The cooling line equipment 514 comprises a cooling line 506 having two separation membranes 524 and 524′, each in the form of a tube 526, 526′. In contrast to the embodiment in FIG. 8, however, the separation membranes 524 and 524′ are not arranged coaxially in cross-sectional view, but side by side. Each of the tubes 526, 526′ is filled with a gas 222 for providing a compressible gas volume 516, 516′ for damping pressure fluctuations of the cooling liquid 112. The embodiment shown in FIG. 9 is an example of two interior gas spaces 520, 520′.

In a variant of the embodiment of FIG. 9 (not shown here), two liquid spaces formed within the tubes 526, 526′ may also be provided. Furthermore, a gas space arranged between an outer wall 530, 530′ of the tubes 526, 526′ and an inner wall 532 of the cooling line 506 may be provided.

FIG. 10 shows a cross-sectional view of a further embodiment of cooling line equipment 614 of a cooling device 600 of the lithography apparatus 1. The cooling line equipment 614 is a variant of the cooling line equipment 214 shown in FIG. 5. The cooling line equipment 614 according to the embodiment of FIG. 10 differs from the cooling line equipment 214 according to the embodiment of FIG. 5 in that a plurality of spacers 638 are arranged on the separation membrane 624. By way of example, three of the spacers 638 shown are provided with a reference sign in FIG. 10. In particular, the spacers 638 are arranged between an outer wall 630 of the elastic separation membrane 624 and an inner wall 632 of the cooling line 606. For example, the spacers 638 are formed by nubs 640 arranged on the outer wall 630 of the elastic separation membrane 624. In particular, the nubs 640 might be formed from the same material as the elastic separation membrane 624. For example, the nubs may also be formed in one piece with the elastic separation membrane 624.

FIG. 11 shows a perspective view of a further embodiment of cooling line equipment 714 of a cooling device 700 of the lithography apparatus 1. The cooling line equipment 714 in particular comprises a securing element 742 for attaching the elastic separation membrane 724 to an inner wall 732 of the cooling line 706. The elastic separation membrane 724 is in particular embodied in the form of a tube 726. Furthermore, the securing element 742 for example comprise a pipe clamp 744, which is arranged around the tube 726 and to which the tube 726 is clamped. The securing element 742 moreover for example comprise a strut and/or a connecting piece 746, which connects the pipe clamp 744 to an inner wall 732 of the cooling line 706. In particular, the strut/connecting piece 746 is attached on one of its sides to the pipe clamp 744 and attached on its other side to the inner wall 732 of the cooling line 706. In particular, the strut/connecting piece 746 is an example of a spacer which holds the tube 726 in position within the liquid space 718 filled with the cooling liquid 112.

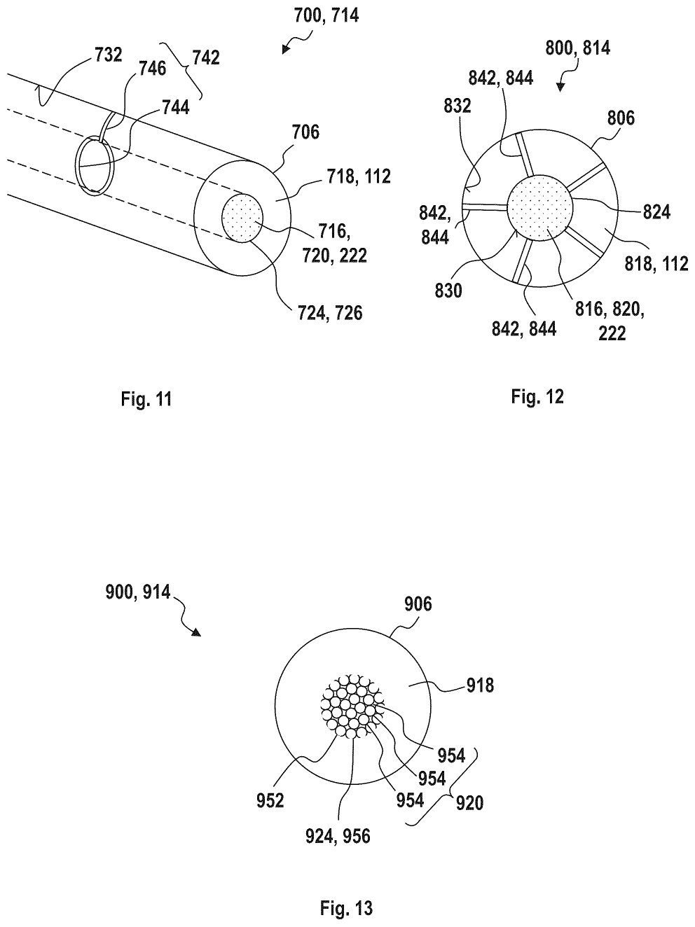

FIG. 12 shows a perspective view of a further embodiment of cooling line equipment 814 of a cooling device 800 of the lithography apparatus 1. The cooling line equipment 814 comprises a securing element 842 according to a further variant. The securing element 842 comprise struts 844 that are arranged between an outer wall 830 of the separation membrane 824 and an inner wall 832 of the cooling line 806. The struts are arranged radially in particular. Five struts, three of which have been provided with a reference sign, are shown in FIG. 12 by way of example. FIG. 12 shows an interior gas space 820 which is surrounded by a ring-shaped liquid space 818; however, this arrangement may also be reversed such that an exterior gas space and an interior liquid space are present.

The embodiments of the cooling line equipment 214, 214′, 214″, 314, 414, 514, 614, 714 and 814 shown in FIGS. 3 to 12 may be combined in many ways. For example, the spacers 638 shown in FIG. 10, the securing element 742 shown in FIG. 11 and the securing element 842 shown in FIG. 12 may be combined with each of the embodiments and variants shown and/or described in connection with FIGS. 3 to 9.

FIGS. 8 and 9 show two examples of cooling line equipment 414 and 514 in which more than one separation membrane 424, 524 is provided in order, as seen in the cross section of the cooling line 406, 506, to provide more than one gas space 420, 520 for damping pressure fluctuations of the cooling liquid 112. In particular, FIGS. 8 and 9 each show two separation membranes 424 and 424′ and 524 and 524′, respectively, for the formation of two gas spaces 420 and 420′ and 520 and 520′, respectively. However, more than two separation membranes may be provided so that, as seen in the cross section of the cooling line 406, 506, more than two gas spaces are provided.

As shown in FIG. 3, more than two separation membranes 224, 224″ may additionally or alternatively be provided such that, in relation to a flow direction (direction of flow) R of the cooling liquid 112, they are separated from one another and from the liquid space 218. Furthermore, the cooling device 200 may comprise two or more gas spaces 220, 220″, which are separated from the liquid space 218 with the aid of the two or more separation membranes 224, 224″. In relation to the flow direction (direction of flow) R of the cooling liquid 112 in particular, the two or more gas spaces 220, 220″ are separated from one another and from the liquid space 218. A gas 222, 222″ is received in each of the two or more gas spaces 220, 220″, wherein the gases 222, 222″ may have pressures P, P″ differing from one another. The pressures P, P″ refer in particular to pressures of the gases 222, 222″ (preload pressures) in a rest state of the separation membrane 224, 224″.

By providing a plurality of gas volumes 216, 216″ with differing preload pressures P, P″ in the cooling circuit 202, pressure fluctuations of the cooling liquid 112 in the cooling circuit 202 can be dampened in a targeted manner. In particular, a frequency range of a damping may be set by setting the preload pressure P, P″ of the respective gas volume 216, 216″. For example, low-frequency pressure surges can be dampened by a first gas volume 216 in the cooling circuit 202 in FIG. 3. For example, it is known that excitations from the water cabinet tend to be low-frequency in nature. Therefore, the first gas volume 216 can be specifically designed for low-frequency suppression, and this may be realized as close as possible to the water cabinet.

Furthermore, higher-frequency pressure surges can for example be dampened by a second gas volume 216″ in the cooling circuit 202 in FIG. 3. In particular, the preload pressure P″ of the second gas volume 216″ is to this end set to a higher value than the preload pressure P of the first gas volume 216. It is known that a sensitive frequency range of between about 50 and 150 Hz is present due to the position control of the mirrors 102. Hence, the second gas volume 216″, which exhibits good suppression exactly in this frequency range, could be arranged directly upstream of the actively controlled and cooled mirrors 102.

For example, a cascading of the pressure damping in the cooling circuit 202 also can be realized in this manner. In the cascading, for example as viewed in the flow direction R of the cooling liquid 112, pressure fluctuations at low frequencies are damped first (e.g. by the first gas volume 216). Then, downstream in the flow direction R, pressure fluctuations at higher frequencies, for example, are damped (e.g. by the second gas volume 216″).

By way of example, FIG. 3 shows two gas volumes 216, 216″ with differing preload pressures P, P″ and hence differing damping properties. However, more than two gas volumes 216, 216″ with differing preload pressures P, P″ and damping properties may also be provided in the cooling circuit 202.

Moreover, gas volumes 216, 216″ can be specifically adapted to the damping requirements of individual position-sensitive components 102, 102′, 102″. In FIG. 3, the three gas volumes 216″, which are upstream of the three optical components 102, 102′, 102″ in the flow direction R, have an equal preload pressure P″. However, a respective preload pressure P″ of a gas volume 216″ may also be specifically adapted to damping requirements of a respective optical component 102, 102′, 102″.

As shown using dashed lines in FIG. 3, the cooling device 200 may comprise one or more pieces of equipment 250 for setting a pressure P, P″ of the gas 222, 222″ in one or more gas volumes 216, 216″. Damping properties of closed gas volumes 216, 216″ over the entire cooling circuit 202 may be selectively set by the one or more pieces of pressure setting equipment 250. For example, the preload pressures P, P″ are set before putting the cooling device 200 and/or the lithography apparatus 1 into operation.

Although not shown in FIGS. 4 to 12, the embodiments of the cooling devices 300, 400, 500, 600, 700, 800 may comprise one or more pieces of equipment similar to the equipment 250 (FIG. 3) for setting a pressure of the gas 222 in one or more gas spaces 320, 420, 420′, 520, 520′, 620, 720, 820.

As seen in the flow direction in each case, FIGS. 3 to 12 show closed gas spaces 320, 420, 420′, 520, 520′, 620, 720, 820. However, in other examples, a single gas space may be guided through the entire cooling circuit 202.

FIG. 13 shows a cross-sectional view of a further embodiment of cooling line equipment 914 of a cooling device 900 of the lithography apparatus 1. The cooling device 900 comprises a cooling line 906 having a liquid space 918, a gas space 920 and a separation membrane 924 separating off the liquid space 918. According to this embodiment, the cooling device 900 furthermore comprises a foam-like and/or sponge-like element 952. The foam-like and/or sponge-like element 952 comprises a plurality of bubbles 954 (gas bubbles 954) and an elastic material 956 surrounding the plurality of bubbles 954. The gas space 920 is formed in particular by the plurality of bubbles 954 of the foam-like and/or sponge-like element 952. Furthermore, the elastic material 956 surrounding the plurality of bubbles 954 forms the separation membrane 924.

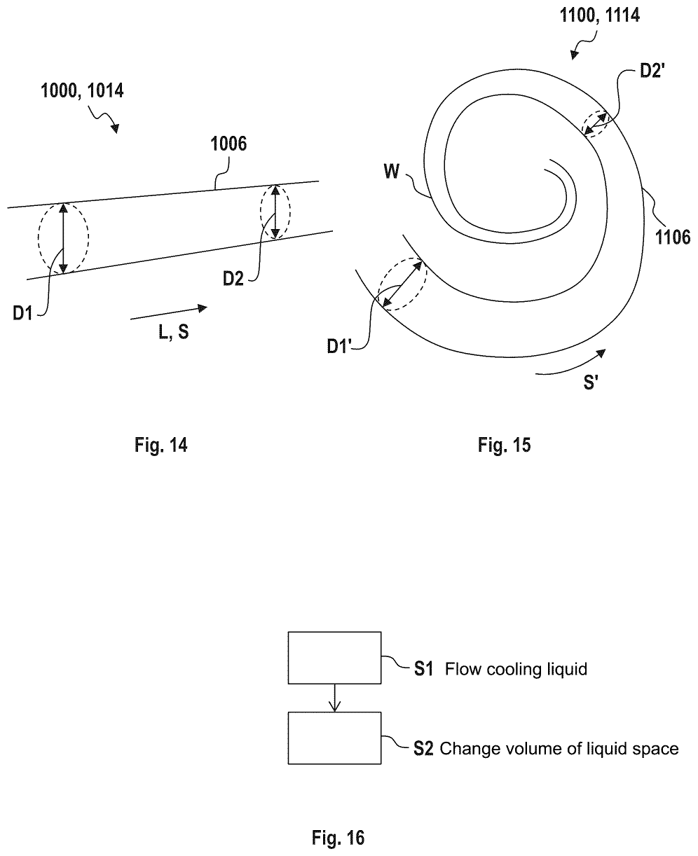

FIG. 14 shows a side view of a further embodiment of cooling line equipment 1014 of a cooling device 1000 of the lithography apparatus 1. The cooling device 1000 comprises a cooling line 1006. Although not shown in FIG. 14, the cooling line 1006-like the cooling lines described above-comprises a liquid space, a gas space and a separation membrane separating off the liquid space. According to this embodiment, the cooling device 1000 is configured to allow a cooling liquid to flow through the cooling line 1006 in a flow direction R. Furthermore, a diameter of the cooling line 1006 tapers (e.g. uniformly) in the flow direction R. The reference sign D1 denotes a first diameter, and D2 denotes a second diameter, which is smaller than the first diameter D1. The flow speed of the cooling liquid can be influenced by the taper of the cooling line diameter. A frequency range of damping of pressure waves of the cooling liquid can be set thereby.

In the example shown in FIG. 14, the cooling line 1006 extends linearly in a longitudinal direction L, and the cooling liquid flows through the cooling line 1006 in the longitudinal direction L. In other words, the flow direction R and the longitudinal direction L are arranged parallel to each other in this case. In FIG. 14, the diameter of the cooling line 1006 tapers in the longitudinal direction L.

FIG. 15 shows a further variant of a cooling line 1114 of a cooling device 1100, said cooling line tapering in a flow direction R′ of a cooling liquid. In particular, the cooling line 1114 in FIG. 15 is curved. In the example shown, the cooling line 1114 is shaped like a helix W. The diameter of the cooling line 1114 tapers along the helically W curved cooling line 1114. The reference sign D1′ denotes a first diameter, and D2′ denotes a second diameter which is smaller than the first diameter D1′.

In the following, with reference to FIG. 16, a method for operating a cooling device 200, 200′, 300, 400, 500, 600, 700, 800, 900, 1000, 1100 (FIGS. 4 to 15) of a projection exposure apparatus 1 (FIG. 1) according to one embodiment is described. The cooling device 200, 200′, 300, 400, 500, 600, 700, 800, 900, 1000, 1100 serves to cool a position-sensitive component 102, 102′, 102″ (FIG. 3) of the projection exposure apparatus 1 (FIG. 1).

The cooling device 200, 200′, 300, 400, 500, 600, 700, 800, 900, 1000, 1100 comprises cooling line equipment 214, 214′, 314, 414, 514, 614, 714, 814, 914, 1014, 1114 (FIGS. 4 to 15) with a cooling line 206, 206′, 306, 406, 506, 606, 706, 806, 906, 1006, 1106. The cooling line equipment 214, 214′, 314, 414, 514, 614, 714, 814, 914, 1014, 1114 moreover comprises a liquid space 218, 218′, 318, 418, 518, 618, 718, 818, 918 for transporting a cooling liquid 112 to the position-sensitive component 102, 102′, 102″. For damping pressure fluctuations of the cooling liquid 112, the cooling line equipment 214, 214′, 314, 414, 514, 614, 714, 814, 914, 1014, 1114 moreover comprises one or more gas spaces 220, 220′, 320, 420, 420′, 520, 520′, 620, 720, 820, 920 for receiving a gas 222. The respective gas space 220, 220′, 320, 420, 420′, 520, 520′, 620, 720, 820, 920 is separated from the liquid space 218, 218′, 318, 418, 518, 618, 718, 818, 918 with an elastic separation membrane 224, 224′, 324, 424, 424′, 524, 524′, 624, 724, 824, 924.

In a first step S1 of the method, the cooling liquid 112 flows through the liquid space 218, 218′, 318, 418, 518, 618, 718, 818, 918 of the cooling line 206, 206′, 306, 406, 506, 606, 706, 806, 906, 1006, 1106.

In a second step S2 of the method, a volume VF1 of the liquid space 218, 218′, 318, 418, 518, 618, 718, 818, 918 (and hence a volume VF1 of the cooling liquid 112) is changed by deforming the elastic separation membrane 224, 224′, 324, 424, 424′, 524, 524′, 624, 724, 824, 924. In particular, the volume VF1 of the liquid space 218, 218′, 318, 418, 518, 618, 718, 818, 918 is changed in response to a change in pressure of the cooling liquid 112. By changing the volume VF1 of the liquid space 218, 218′, 318, 418, 518, 618, 718, 818, 918 and hence of the cooling liquid 112, a change in pressure, e.g. a pressure fluctuation, of the cooling liquid 112 can be dampened. This can reduce or prevent transmission of a pressure fluctuation to the position-sensitive component 102, 102′, 102″.

Although the present invention has been described with reference to exemplary embodiments, it is modifiable in various ways. From the disclosure given, those skilled in the art will not only understand the present invention and its attendant advantages, but will also find apparent various changes and modifications to the structures and methods disclosed. The applicant seeks, therefore, to cover all such changes and modifications as fall within the spirit and scope of the invention, as defined by the appended claims, and equivalents thereof.

### LIST OF REFERENCE SIGNS

1 Projection exposure apparatus
2 Illumination system
3 Light source
4 Illumination optical unit
5 Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 Illumination radiation
17 Collector
18 Intermediate focal plane
19 Deflection mirror
20 First facet mirror
21 First facet
22 Second facet mirror
23 Second facet
100 Positioning system
102, 102′, 102″ Optical component
104 Coating
106 Optically active surface
108 Substrate
110, 110′, 110″ Cooling line
112 Cooling liquid
114 Actuator equipment
116 Force frame
118 Actuator
120 Sensor equipment
122 Laser beam
200 Cooling device
202 Cooling circuit
204 Cooling unit
206 Cooling line
208 Pump
210 Valve
212 Deflection
214, 214′ Cooling line equipment
216, 216′, 216″ Gas volume
218, 218′ Liquid space
220, 220′, 220″ Gas space
222, 222″ Gas
224, 224′, 224″ Separation membrane
226 Tube
228 Interior
230 Outer wall
232 Inner wall
250 Equipment (pressure setting equipment)
300 Cooling device
306 Cooling line
314 Cooling line equipment
316 Gas volume
318 Liquid space
320 Gas space
324 Separation membrane
326 Tube
400 Cooling device
406 Cooling line
414 Cooling line equipment
416 Gas volume
418 Liquid space
420, 420′ Gas space
424, 424′ Separation membrane
434 Inner side
436 Outer side
500 Cooling device
506 Cooling line
514 Cooling line equipment
516 Gas volume
518 Liquid space
520 Gas space
524, 524′ Separation membrane
526, 526′ Tube
530, 530′ Outer wall
532 Inner wall
600 Cooling device
606 Cooling line
614 Cooling line equipment
616 Gas volume
618 Liquid space
620 Gas space
624 Separation membrane
630 Outer wall
632 Inner wall
638 Spacer
640 Nub
700 Cooling device
706 Cooling line
714 Cooling line equipment
716 Gas volume
718 Liquid space
720 Gas space
724 Separation membrane
726 Tube
732 Inner wall
742 Securing element
744 Pipe clamp
746 Connecting piece/strut
800 Cooling device
806 Cooling line
814 Cooling line equipment
816 Gas volume
818 Liquid space
820 Gas space
824 Separation membrane
830 Outer wall
832 Inner wall
842 Securing element
844 Strut
900 Cooling device
906 Cooling line
914 Cooling line equipment
918 Liquid space
920 Gas space
924 Separation membrane
952 Element
954 Bubble
956 Material
1000 Cooling device
1006 Cooling line
1100 Cooling device
1106 Cooling line
A1-A3 Axis
D Diameter
D1, D1′ Diameter
D2, D2′ Diameter
L Longitudinal direction
M1-M6 Mirrors
P, P″ Pressure
R, R′ Flow direction
S1-S2 Method steps
V_{F1}, V_{F1}′ Volume
V_{F2}, V_{F2}′ Volume
V_{G1}, V_{G1}′ Volume
V_{G2}, V_{G2}′ Volume
W Helical shape
X Direction
Y Direction
Z Direction

What is claimed is:

1. A cooling device for cooling a position-sensitive component of a lithography apparatus, comprising:
a cooling line having a liquid space configured to transport a cooling liquid to the position-sensitive component and a gas space configured to receive a gas, wherein the cooling line is a pipeline defining a constant cooling line cross section in a flow direction of the cooling liquid in the cooling line, and
an elastic separation membrane arranged within the cooling line and separating the gas space from the liquid space.

2. The cooling device as claimed in claim 1, wherein the elastic separation membrane is a pressure membrane configured to deform in response to a change in pressure of the cooling liquid such that a volume of the gas space changes in accordance with the pressure change.

3. The cooling device as claimed in claim 1, wherein, in the cross section of the cooling line, the gas space separated by the elastic separation membrane is rotationally symmetric.

4. The cooling device as claimed in claim 1, wherein, in the cross section of the cooling line, the liquid space and the gas space that is separated from the liquid space by the elastic separation membrane are arranged coaxially.

5. The cooling device as claimed in claim 1, wherein, in the cross section of the cooling line and in relation to the liquid space, the gas space is an interior gas space or an exterior gas space.

6. The cooling device as claimed in claim 1, further comprising an elastic tube that comprises the elastic separation membrane and forms the gas space.

7. The cooling device as claimed in claim 1, further comprising at least one spacer arranged between the elastic separation membrane and an inner wall of the cooling line.

8. The cooling device as claimed in claim 7, wherein the at least one spacer comprises a plurality of spacers that are formed by nubs arranged on an outer side of the elastic separation membrane.

9. The cooling device as claimed in claim 1, further comprising a securing element configured to attach the elastic separation membrane to an inner wall of the cooling line.

10. The cooling device as claimed in claim 1, further comprising equipment configured to set a pressure of a gas contained in the gas space.

11. The cooling device as claimed in claim 1, wherein the elastic separation membrane comprises at least two elastic separation membranes that are arranged within the cooling line and correspondingly form at least two gas spaces that are separated from one another and from the liquid space.

12. The cooling device as claimed in claim 11, wherein
in the cross section of the cooling line, the at least two gas spaces are separated from one another and from the liquid space, and/or
in relation to a flow direction of the cooling liquid, the at least two gas spaces are separated from one another and from the liquid space.

13. The cooling device as claimed in claim 11, wherein
the at least two gas spaces are separated from one another and from the liquid space in relation to a flow direction of the cooling liquid,
the cooling device has a gas in each of the at least two gas spaces, and
the respective gases have mutually differing pressures.

14. The cooling device as claimed in claim 1, further comprising a foam and/or sponge element with a plurality of bubbles and an elastic material surrounding the plurality of bubbles, wherein the gas space is formed by the plurality of bubbles of the foam and/or sponge element, and the separation membrane is formed by the elastic material that surrounds the plurality of bubbles.

15. A cooling device for cooling a position-sensitive component of a lithography apparatus, comprising:
a cooling line having a liquid space configured to transport a cooling liquid to the position-sensitive component and a gas space configured to receive a gas, and
an elastic separation membrane arranged within the cooling line and separating the gas space from the liquid space,
wherein the cooling device is configured such that a cooling liquid flows through the cooling line in a flow direction, and a diameter of the cooling line is tapered in the flow direction.

16. A lithography apparatus, comprising an illumination system configured to illuminate an object field and a projection system configured to project the object field into an image field, wherein the illumination system and/or the projection system comprises a cooling device as claimed in claim 1.

17. The lithography apparatus as claimed in claim 16 and configured to propagate extreme ultraviolet radiation.

18. A method for operating a cooling device for cooling a position-sensitive component of a lithography apparatus, wherein the cooling device comprises a cooling line having a liquid space for transporting a cooling liquid to the position-sensitive component and a gas space for receiving a gas, the cooling line being a pipeline with a cross section that is constant in a flow direction of the cooling liquid in the cooling line, and an elastic separation membrane arranged within the cooling line and separating the gas space from the liquid space, said method comprising:
a) allowing the cooling liquid to flow through the liquid space of the cooling line, and
b) changing a volume of the liquid space by deforming the elastic separation membrane in response to a change in pressure of the cooling liquid in the liquid space.
